(19) United States
(12) Patent Application Publication
(10) Pub. No.: US 2015/0231723 A1
(43) Pub. Date: Aug. 20, 2015

(54) SOLDER BALL ATTACHING APPARATUS, FLUX DOTTING APPARATUS, AND METHOD OF MANUFACTURING SEMICONDUCTOR PACKAGE

(71) Applicant: Samsung Electronics Co., Ltd., Suwon-Si (KR)

(72) Inventor: Eun-Sun AN, Cheonan-si (KR)

(21) Appl. No.: 14/600,184

(22) Filed: Jan. 20, 2015

(30) Foreign Application Priority Data
Feb. 17, 2014 (KR) 10-2014-0017882

(51) Int. Cl. B23K 3/08; H05K 3/34; H05K 13/04; B23K 3/06

(52) U.S. Cl. CPC B23K 3/082; B23K 3/0623; H05K 3/34; H05K 13/0465; H05K 2203/041

(57) ABSTRACT

A solder ball attaching apparatus includes first protrusions on a surface of a first body and a first vacuum part connected to the first vacuum holes. The first protrusions include first vacuum holes and are configured to detachedly hold solder balls. A distance between adjacent ones of the first protrusions is greater than at least a diameter of the solder balls.

### CROSS-REFERENCE TO RELATED APPLICATION

This U.S. non-provisional patent application claims priority under 35 U.S.C. §119 to Korean Patent Application No. 10-2014-0017882, filed on Feb. 17, 2014, in the Korean Intellectual Property Office, the disclosure of which is hereby incorporated by reference in its entirety.

### BACKGROUND

1. Field

Some example embodiments of the inventive concepts relate to a semiconductor manufacturing apparatus and/or a method of manufacturing a semiconductor package and, more particularly, to a solder ball attaching apparatus, a flux dotting apparatus, and/or a method of manufacturing a semiconductor package.

2. Description of the Related Art

Semiconductor devices are widely used in the electronic industry because of their relatively small size, multi-functional capabilities, and/or relatively low manufacture costs. Semiconductor devices have been highly integrated with the development of the electronic industry. In addition, semiconductor packages have also been highly integrated. For example, distances between pads formed on a substrate (e.g., a printed circuit board) may be reduced by the relatively high integration of the semiconductor packages. Thus, bonding solder balls on the pads may be difficult.

### SUMMARY

An example embodiment of the inventive concepts may provide a solder ball attaching apparatus capable of more easily bonding solder balls to a highly integrated semiconductor package.

Another example embodiment of the inventive concepts may also provide a flux dotting apparatus capable of more easily bonding solder balls to a highly integrated semiconductor package.

Another example embodiment of the inventive concepts may also provide a method of manufacturing a semiconductor package using the apparatuses.

According to an example embodiment of the inventive concepts, a solder ball attaching apparatus includes first protrusions on a surface of a first body, the first protrusions including first vacuum holes and configured to detachedly hold solder balls, and a first vacuum part connected to the first vacuum holes. A distance between adjacent ones of the first protrusions is greater than at least a diameter of the solder balls.

In an example embodiment, each of the first protrusions may protrude from the surface of the first body by a height greater than at least the diameter of the solder balls.

In an example embodiment, the solder ball attaching apparatus may further include second protrusions on a surface of a second body, the second protrusions including second vacuum holes and configured to detachedly hold solder balls, wherein a distance between adjacent ones of the second protrusions is greater than at least the diameter of the solder balls.

In an example embodiment, the first body may be on the second body, and one of the second protrusions may be between adjacent ones of the first protrusions.

In an example embodiment, the solder ball attaching apparatus may further include a first vacuum line connected to the first vacuum holes and the first vacuum part, a first valve on the first vacuum line, a second vacuum line connected to the second vacuum holes and the first vacuum part, and a second valve on the second vacuum line.

In an example embodiment, the solder ball attaching apparatus may further include a second vacuum part connected to the second vacuum holes.

In an example embodiment, the first body may include second vacuum holes extending from the surface of the first body between the adjacent ones of the first protrusions and into the first body.

In an example embodiment, the solder ball attaching apparatus may further include a second vacuum part connected to the second vacuum holes.

In an example embodiment, the solder ball attaching apparatus may further include a first vacuum line connected to the first vacuum holes and the first vacuum part, a first valve on the first vacuum line, a second vacuum line connected to the second vacuum holes and the second vacuum part, and a second valve on the second vacuum line.

According to another example embodiment of the inventive concepts, a flux dotting apparatus includes a first body, and a plurality of first pins on a surface of the first body, the first pins separated from one another by a distance greater than at least a diameter of a solder ball.

In another example embodiment, the flux dotting apparatus may further include a second body, and a plurality of second pins on a surface of the second body, the second pins separated from one another by a distance greater than at least the diameter of the solder ball.

In another example embodiment, the first body may be on the second body, and one of the second pins may be between adjacent ones of the first pins.

According to yet another example embodiment of the inventive concepts, a method of manufacturing a semiconductor package includes preparing a substrate including first pads and second pads that are alternately disposed, dotting flux on the first pads, dotting flux on the second pads, attaching first solder balls to the first pads on which the flux is dotted, attaching second solder balls to the second pads on which the flux is dotted, and bonding the first solder balls to the first pads and the second solder balls to the second pads by performing a reflow process on the first pads having the first solder balls and the second pads having the second solder balls.

In yet another example embodiment, bonding the first solder balls to the first pads and the second solder balls to the second pads may react the first solder balls with the flux on the first pads and the second solder balls with the flux on the second pads during the reflowing process.

In yet another example embodiment, the method may further include cleaning the substrate including the first and second pads having the first and second solder balls bonded thereto, respectively.

According to still another example embodiment of the inventive concepts, a solder ball attaching apparatus includes a plurality of first hollow mesas extending in a direction perpendicular to a surface of a first body, the plurality of first hollow mesas defining first vacuum holes configured to detachedly hold solder balls, and a first vacuum line extending in a direction parallel to the surface of the first body, the first vacuum line connecting the first vacuum holes.

In still another example embodiment, each of the plurality of first hollow mesas may protrude from the surface of the first body by a height greater than at least the diameter of the solder balls.

In still another example embodiment, the solder ball attaching apparatus may further include a plurality of second hollow mesas on a surface of a second body, the plurality of second hollow mesas including second vacuum holes and configured to detachedly hold solder balls, and a second vacuum line extending in a direction parallel to the surface of the second body, the second vacuum line connecting the second vacuum holes, wherein a distance between adjacent ones of the plurality of second hollow mesas is greater than at least the diameter of the solder balls.

In still another example embodiment, the solder ball attaching apparatus may further include a first vacuum part connected to the first vacuum holes, a second vacuum part connected to the second vacuum holes, a first valve on the first vacuum line connected to the first body, and a second valve on the second vacuum line connected to the second body, wherein the first vacuum line is connected to the first vacuum part and the second vacuum line is connected to the second vacuum part.

In still another example embodiment, the first vacuum part may be connected to the first body by a surface opposite to the surface including the plurality of first hollow mesas, and the second vacuum part may be connected to the second body by a surface opposite to the surface including the plurality of second hollow mesas.

In still another example embodiment, a first set of the first vacuum holes may penetrate the plurality of first hollow mesas and a second set of the first vacuum holes may extend into the first body between adjacent ones of the plurality of first hollow mesas.

In still another example embodiment, the solder ball attaching apparatus may further include a first vacuum part connected to the first set of the first vacuum holes, and a second vacuum part connected to the second set of the second vacuum holes.

In still another example embodiment, the solder ball attaching apparatus may further include a first vacuum line connected to the first set of the first vacuum holes and the first vacuum part, a first valve on the first vacuum line, a second vacuum line connected to the second set of the first vacuum holes and the second vacuum part, and a second valve on the second vacuum line.

### BRIEF DESCRIPTION OF THE DRAWINGS

The inventive concepts will become more apparent in view of the attached drawings and accompanying detailed description.

FIG. 1 is a diagram illustrating a manufacturing apparatus of a semiconductor package according to an example embodiment of the inventive concepts;

FIGS. 2A through 2D are plan views and cross-sectional views illustrating a solder ball attaching apparatus according to an example embodiment of the inventive concepts;

FIGS. 3A through 3C are a plan view and cross-sectional views illustrating solder ball attaching apparatuses according to an example embodiment of the inventive concepts;

FIGS. 4A through 4D are plan views and cross-sectional views illustrating flux dotting apparatuses according to an example embodiment of the inventive concepts; and

FIGS. 5A through 5G are cross-sectional views illustrating a method of manufacturing a semiconductor package according to an example embodiment of the inventive concepts.

### DETAILED DESCRIPTION

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, example embodiments are provided only to disclose the inventive concepts and let those skilled in the art know the category of the inventive concepts. In the drawings, example embodiments of the inventive concepts are not limited to the specific examples provided herein and are exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal example views of the inventive concepts. Accordingly, shapes of the example views may be modified according to manufacturing techniques and/or allowable errors. Therefore, the embodiments of the inventive concepts are not limited to the specific shape illustrated in the example views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present inventive concepts. Example embodiments of the present inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

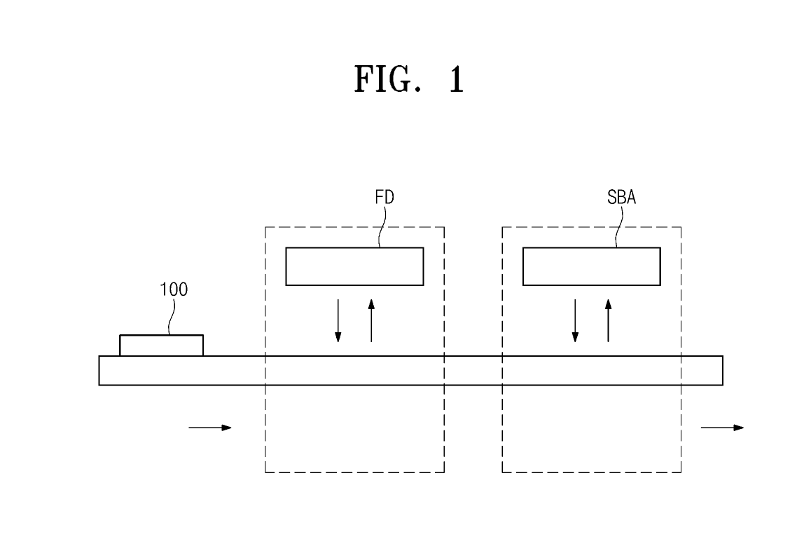

FIG. 1 is a diagram illustrating a manufacturing apparatus of a semiconductor package according to an example embodiment of the inventive concepts.

Referring to FIG. 1, a substrate 100 having a plurality of pads (not shown) may be provided. The substrate 100 may be included in a semiconductor package. The substrate 100 may be a printed circuit board (PCB), a semiconductor chip, or an interposer.

The substrate 100 may be moved to a flux dotting apparatus FD to provide flux onto the pads. The substrate 100 may be moved to a solder ball attaching apparatus SBA to bond solder balls onto the pads on which the flux is provided.

Hereinafter, the flux dotting apparatus FD and the solder ball attaching apparatus SBA will be described in more detail.

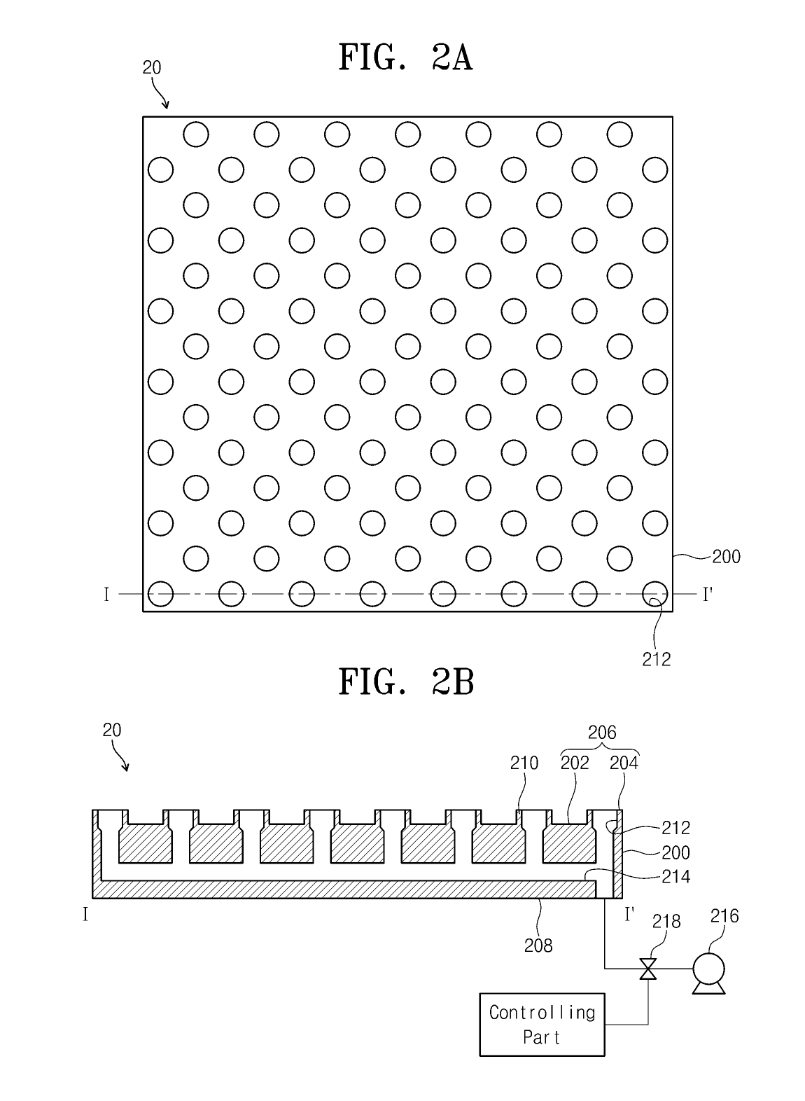

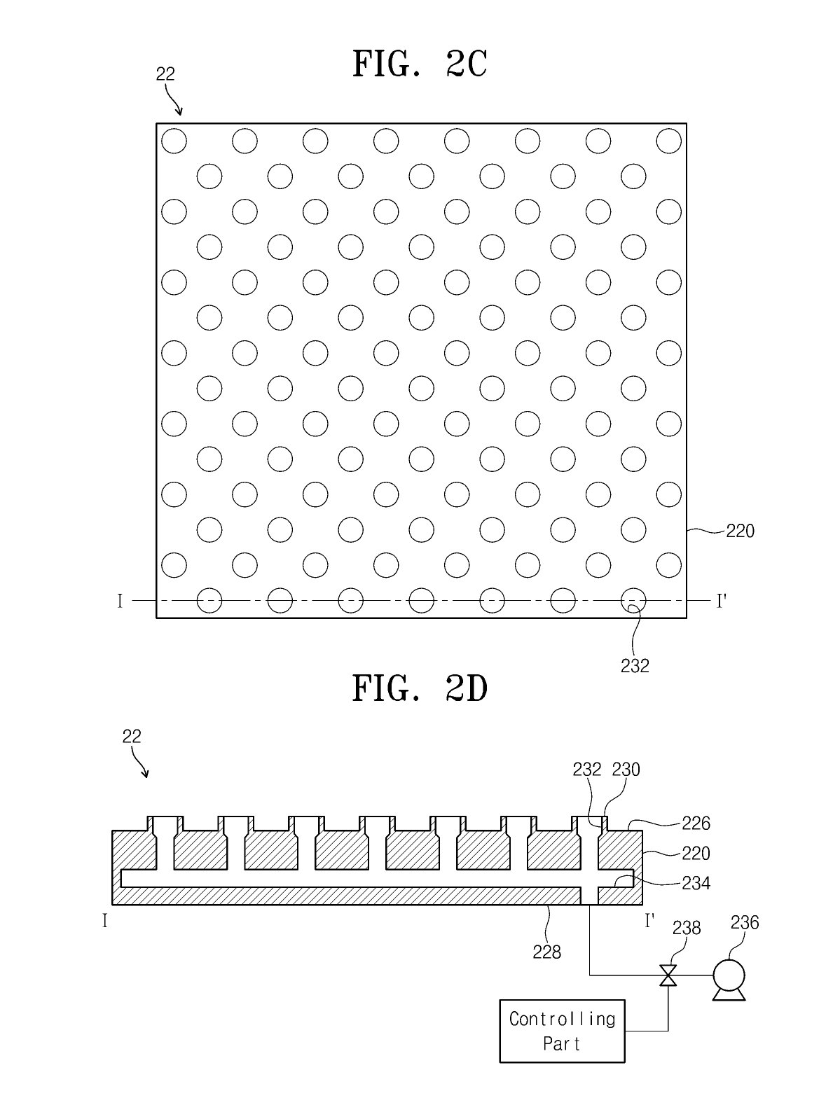

FIGS. 2A through 2D are plan views and cross-sectional views illustrating a solder ball attaching apparatus according to an example embodiment of the inventive concepts. FIGS. 2A and 2C are plan views, FIG. 2B is a cross-sectional view taken along a line I-I′ of FIG. 2A, and FIG. 2D is a cross-sectional view taken along a line I-I′ of FIG. 2C.

Referring to FIGS. 1 and 2A through 2D, a solder ball attaching apparatus may include a first solder ball attaching apparatus 20 and a second solder ball attaching apparatus 22.

The first solder ball attaching apparatus 20 may include a first body 200, a first vacuum line 214, and a first vacuum part 216.

The first body 200 may have the substantially same shape as a package on which the solder balls are bonded. For example, the first body 200 may have a quadrilateral shape when viewed from a plan view. However, the inventive concepts are not limited to the shape of the first body 200.

The first body 200 may include an attachment surface 206 for attaching the solder balls and a connection surface 208 connected to the first vacuum part 216. A position of the attachment surface 206 may be different from a position of the connection surface 208. For example, the attachment surface 206 may be opposite to the connection surface 208.

The attachment surface 206 may include a plurality of first protrusions (or hollow mesas) 210. The attachment surface 206 may include a first surface 202 and second surfaces 204 higher than the first surface 202. The second surfaces 204 may be top surfaces of the first protrusions (or hollow mesas) 210. In an example embodiment, a height difference between the first surface 202 and the second surface 204 may be greater than at least a diameter of the solder ball.

In an example embodiment, the first protrusions (or hollow mesas) 210 may be spaced apart from each other along rows and columns. A direction parallel to the rows is defined as a row direction, and a direction parallel to the columns is defined as a column direction.

In more detail, when a first column, a second column, and a third column are sequentially arranged in the row direction, the first protrusions (or hollow mesas) 210 of the first column and the first protrusions (or hollow mesas) 210 of the second column may be arranged in a zigzag form along the column direction. The first protrusions (or hollow mesas) 210 of the third column may be respectively aligned with the first protrusions (or hollow mesas) 210 of the first column along the row direction. In addition, when a first row, a second row, and a third row are sequentially arranged in the column direction, the first protrusions (or hollow mesas) 210 of the first row and the second protrusions (or hollow mesas) 210 of the second row may be arranged in a zigzag form along the row direction. The first protrusions (or hollow mesas) 210 of the third row may be respectively aligned with the first protrusions (or hollow mesas) 210 of the first row in the column direction.

In addition, a distance between the first two protrusions (or hollow mesas) 210 adjacent to each other may be greater than the diameter of the solder ball. One of the first protrusions (or hollow mesas) 210 may be spaced apart from first four protrusions (or hollow mesas) 210 surrounding the one of the first protrusions (or hollow mesas) 210 by equal distances.

The first body 200 may include first vacuum holes 212. Each of the first vacuum holes 212 may provide a space temporarily holding the solder ball. A size of each of the first vacuum holes 212 may be greater than at least the diameter of the solder ball. In an example embodiment, each of the first vacuum holes 212 may penetrate each of the first protrusions (or hollow mesas) 210. In more detail, each of the first vacuum holes 212 may extend in a direction perpendicular to the attachment surface 206.

The first vacuum holes 212 may be connected to the first vacuum line 214. The first vacuum line 214 may connect the first vacuum holes 212 to the first vacuum part 216. In more detail, the first vacuum line 214 may extend within the first body 200 in substantially parallel to the attachment surface 206 and may be connected to the first vacuum holes 212.

A first valve 218 may be installed on the first vacuum line 214. The first valve 218 may be connected to a controlling part. The controlling part may control the opening and closing of the first valve 218.

The second solder ball attaching apparatus 22 may include a second body 220, a second vacuum line 234, and a second vacuum part 236.

The second body 220 may include an attachment surface 226 and a connection surface 228. A plurality of second protrusions (or hollow mesas) 230 may be disposed on the attachment surface. In addition, the second body 220 may include second vacuum holes 232 penetrating the second protrusions (or hollow mesas) 230.

The second solder ball attaching apparatus 22 may be the substantially same as the first solder ball attaching apparatus 20. However, positions of the second protrusions (or hollow mesas) 230 of the second solder ball attaching apparatus 22 may be different from positions of the first protrusions (or hollow mesas) 210 of the first solder ball attaching apparatus 20. In more detail, when a structure and a shape of the second body 220 are the same as the structure and the shape of the first body 200, the second protrusions (or hollow mesas) 230 may be disposed to correspond to the first surface 202 of the attachment 206 of the first solder ball attaching apparatus 20. Thus, when the first body 200 is stacked on the second body 220, the first protrusions (or hollow mesas) 210 and the second protrusions (or hollow mesas) 220 may be alternately arranged.

The second body 220, the second vacuum line 234, and the second vacuum part 236 may be similar to the first body 200, the first vacuum line 214, and the first vacuum part 216, so the descriptions thereto will be omitted.

In the present embodiment, two solder ball attaching apparatuses 20 and 22 are illustrated as an example. However, the inventive concepts are not limited thereto. In an example embodiment, the solder ball attaching apparatus may include three or more solder ball attaching apparatuses.

As described above, the solder ball attaching apparatus includes the plurality of solder ball attaching apparatuses. The solder balls to be attached to the pads of the substrate 100 may be divided into a plurality of ball groups respectively corresponding to the plurality of solder ball attaching apparatuses. Each of the ball groups may include a plurality of solder balls. The plurality of ball groups may be attached to the pads of the substrate 100 by the plurality of solder ball attaching apparatuses, respectively. Thus, even though distances between the pads of the substrate 100 are small or narrow, the solder balls may be more easily attached to the pads of the substrate 100 by the plurality of solder ball attaching apparatuses. In addition, since the plurality of vacuum parts is used, a sufficient vacuum pressure may be provided to the vacuum holes.

In a modified embodiment of the present embodiment, the first vacuum part 216 and the second vacuum part 236 may be replaced with one vacuum part. A second valve 238 may be installed on the second vacuum line 234 and may be connected to the controlling part. The first valve 218 and the second valve 238 may be connected to the one vacuum part. The controlling part may control opening and closing of the first and second valves 218 and 238, so the first and second solder ball attaching apparatuses may perform the process of attaching solder balls using the one vacuum part.

When the one vacuum part provides the vacuum pressure to one of the two solder ball attaching apparatuses, the vacuum pressure may not be provided to the other of the two solder ball attaching apparatuses. Thus, a sufficient vacuum pressure may be provided to the one solder ball attaching apparatus.

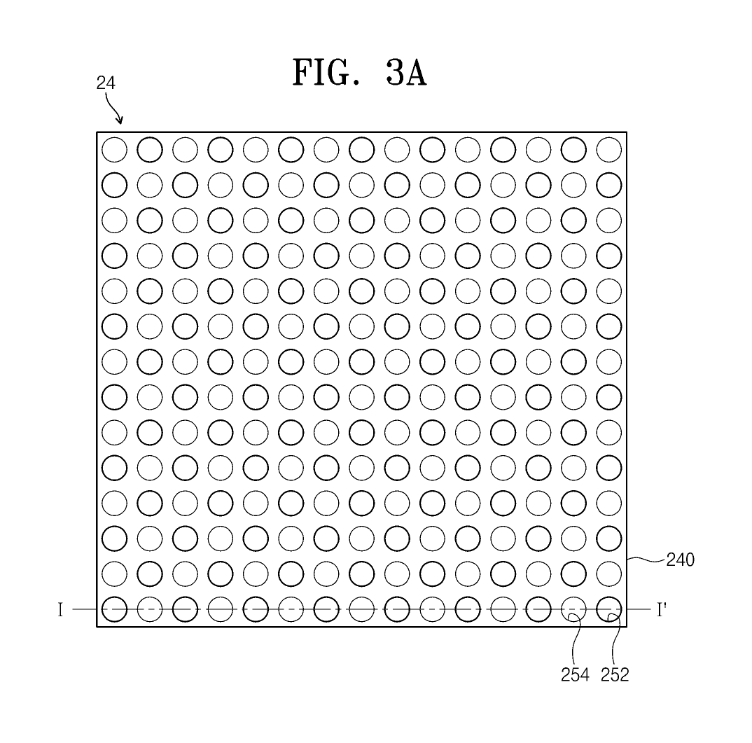

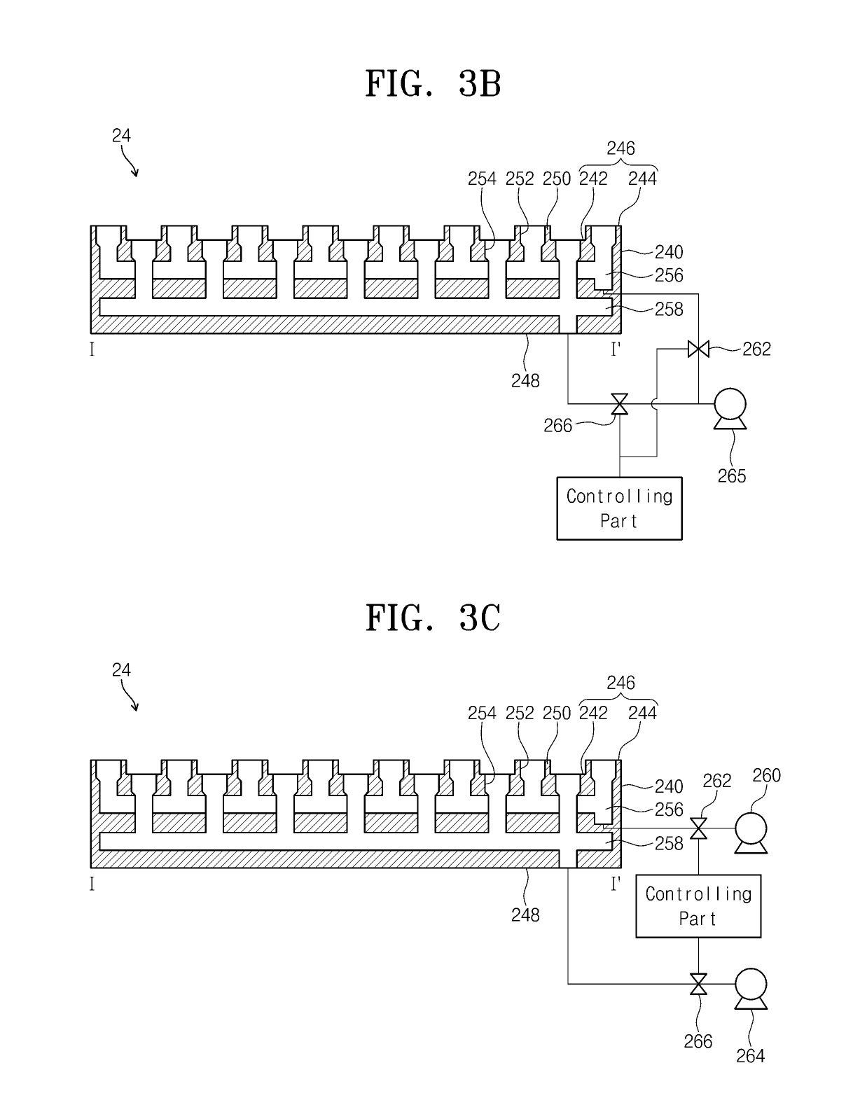

FIG. 3A is a plan view illustrating a solder ball attaching apparatus according to another example embodiment of the inventive concepts, and FIG. 3B is a cross-sectional view taken along a line I-I′ of FIG. 3A.

Referring to FIGS. 1, 3A and 3B, a solder ball attaching apparatus 24 may include a body 240, a first vacuum line 256, a second vacuum line 258, and a vacuum part 265.

The body 240 may include an attachment surface 246 and a connection surface 248. A plurality of protrusions (or hollow mesas) 250 may be formed on the attachment surface 246. The attachment surface 246 may include a first surface 242 and a plurality of a second surfaces 244 higher than the first surface 242. The second surfaces 244 may be top surfaces of the protrusions (or hollow mesas) 250. A height difference between the first and second surfaces 242 and 244 may be greater than the diameter of the solder ball.

The plurality of protrusions (or hollow mesas) 250 may be arranged along rows and columns. The protrusions (or hollow mesas) 250 of one column may be spaced apart from each other by a distance greater than the diameter of the solder ball. The protrusions (or hollow mesas) 250 of one row may be spaced apart from each other by a distance greater than the diameter of the solder ball.

When a first column, a second column, and a third column are sequentially arranged in a row direction, the protrusions (or hollow mesas) 250 of the first column and the protrusions (or hollow mesas) 250 of the second column may be arranged in a zigzag form along a column direction. The protrusions (or hollow mesas) 250 of the third column may be respectively aligned with the protrusions (or hollow mesas) 250 of the first column in the row direction.

When a first row, a second row, and a third row are sequentially arranged in the column direction, the protrusions (or hollow mesas) 250 of the first row and the protrusions (or hollow mesas) 250 of the second row may be arranged in zigzag form along the row direction. The protrusions (or hollow mesas) 250 of the third row may be respectively aligned with the protrusions (or hollow mesas) 250 of the first row in the column direction.

The body 240 may include first vacuum holes 252 and second vacuum holes 254. The first vacuum holes 252 may penetrate the protrusions (or hollow mesas) 250, and the second vacuum holes 254 may extend from the first surface 242 between the protrusions (or hollow mesas) 250 into the body 240. A distance between the first vacuum holes 252 adjacent to each other may be greater than at least the diameter of the solder ball, and a distance between the second vacuum holes 254 adjacent to each other may also be greater than at least the diameter of the solder ball. In addition, a diameter of each of the first and second vacuum holes 252 and 254 may be greater than at least the diameter of the solder ball.

When the first row, the second row, and the third row are sequentially disposed in the column direction, the second vacuum holes 254 may be disposed between the first vacuum holes 252 of each of the first to third rows. In other words, the first vacuum holes 252 and the second vacuum holes 254 may be alternately arranged along the row direction in each of the first to third rows. The first vacuum holes 252 of the second row may be respectively aligned with the second vacuum holes 254 of the first row in the column direction. The second vacuum holes 254 of the second row may be respectively aligned with the first vacuum holes 252 of the first row in the column direction. The first vacuum holes 252 and the second vacuum holes 254 of the third row may be respectively aligned with the first vacuum holes 252 and the second vacuum holes 254 of the first row in the column direction.

Likewise, when the first column, the second column, and the third column are sequentially disposed in the row direction, the second vacuum holes 254 may be disposed between the first vacuum holes 252 of each of the first to third columns. In other words, the first vacuum holes 252 and the second vacuum holes 254 may be alternately arranged along the column direction in each of the first to third columns. The first vacuum holes 252 of the second column may be respectively aligned with the second vacuum holes 254 of the first column in the row direction. The second vacuum holes 254 of the second column may be respectively aligned with the first vacuum holes 252 of the first column in the row direction. The first vacuum holes 252 and the second vacuum holes 254 of the third column may be respectively aligned with the first vacuum holes 252 and the second vacuum holes 254 of the first column in the row direction.

The first vacuum holes 252 may be connected to the first vacuum line 256, and the first vacuum line 256 may be connected to the vacuum part 265. A first valve 262 may be installed on the first vacuum line 256. The second vacuum holes 254 may be connected to the second vacuum line 258, and the second vacuum line 258 may be connected to the vacuum part 265. A second valve 266 may be installed on the second vacuum line 258.

The first and second valves 262 and 266 may be connected to a controlling part. Opening and closing of each of the first and second valves 262 and 266 may be controlled by the controlling part. For example, when the solder balls are attached using the first vacuum holes 252 of the body 240, the first valve 262 may be opened and the second valve 266 may be closed. Thus, a vacuum pressure may be provided to the first vacuum holes 252. When the solder balls are attacked using the second vacuum holes 254 of the body 240, the second valve 266 may be opened and the first valve 262 may be closed. Thus, the vacuum pressure may be provided to the second vacuum holes 254.

Accordingly, the vacuum pressure may not be provided to the second vacuum holes 254 while the solder balls are held in the first vacuum holes 252. Thus, the vacuum pressure may be sufficiently provided to the first vacuum holes 252.

FIG. 3C is a cross-sectional view taken along a line I-I′ of FIG. 3A to illustrate a modified embodiment of the solder ball attaching apparatus of FIG. 3A.

Referring to FIGS. 3A and 3C, in the present modified embodiment, the vacuum part may include a first vacuum part 260 and a second vacuum part 264. The first vacuum part 260 may be connected to the first vacuum line 256, and the second vacuum part 264 may be connected to the second vacuum line 258.

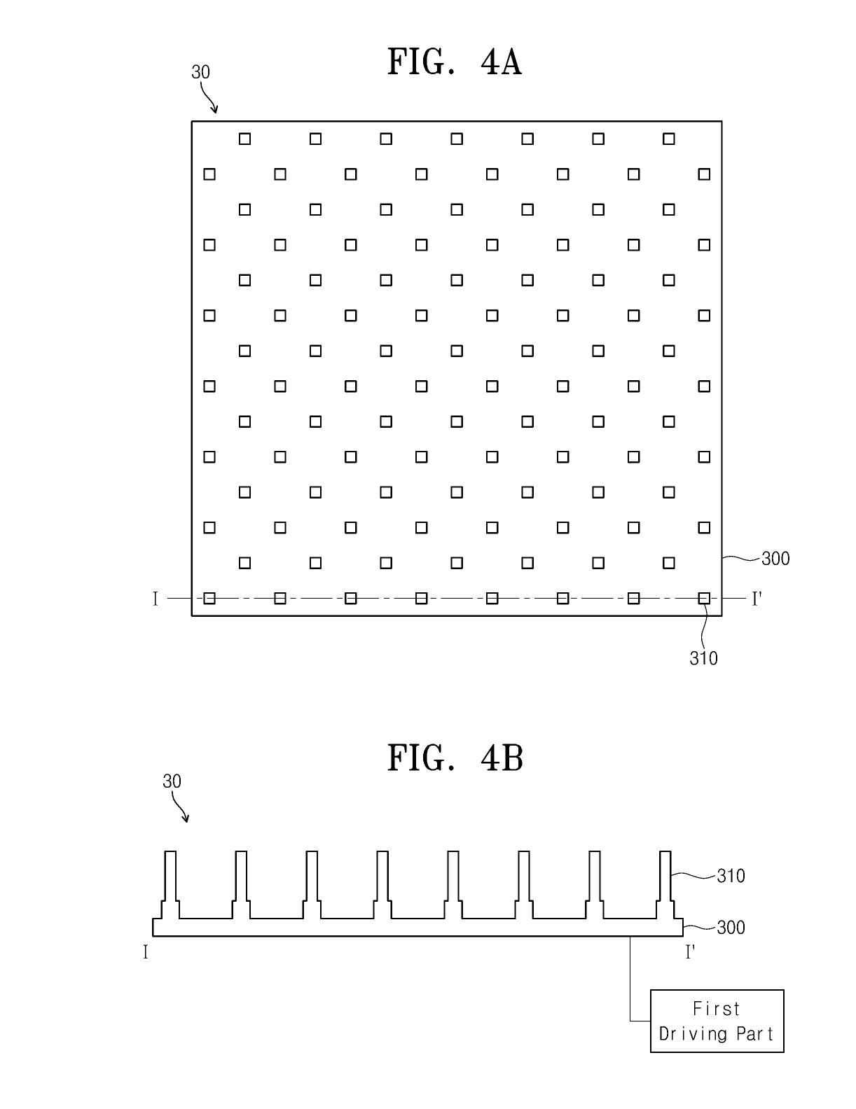

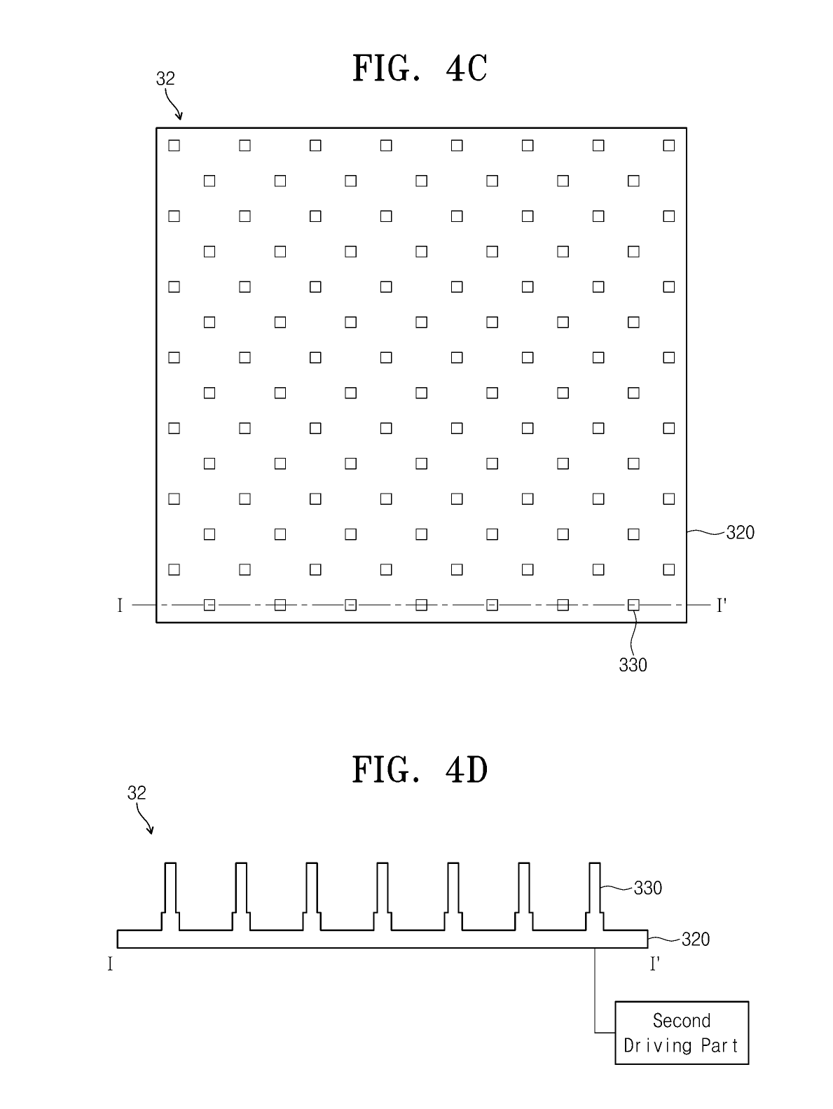

FIGS. 4A through 4D are plan views and cross-sectional views illustrating flux dotting apparatuses according to an example embodiment of the inventive concepts. FIGS. 4A and 4C are plan views, FIG. 4B is a cross-sectional view taken along a line I-I′ of FIG. 4A, and FIG. 4C is a cross-sectional view taken along a line I-I′ of FIG. 4D.

Referring to FIGS. 1, 4A through 4D, a flux dotting apparatus may include a first dotting part 30 and a second dotting part 32.

The first dotting part 30 may include a first body 300 and a plurality of first pins 310 extending from the first body 300 in one direction. The first pins 310 may have a circular or polygonal cross section. However, the inventive concepts are not limited to the shape of the cross section of the first pin 310.

In an example embodiment, the first pins 310 may be arranged along rows and columns. A distance between the first pins 310 adjacent to each other in each row may be greater than at least a diameter of a solder ball. In addition, a distance between the first pins 310 adjacent to each other in each column may be greater than the diameter of the solder ball.

A first row, a second row, and a third row may be sequentially disposed in a column direction parallel to the columns. Each of the first pins 310 of the second row may be disposed between the first pins 310 adjacent to each other of the first row when viewed from the column direction. The first pins 310 of the third row may be respectively aligned with the first pins 310 of the first row in the column direction.

A first column, a second column, and a third column may be sequentially disposed in a row direction parallel to the rows. Each of the first pins 310 of the second column may be disposed between the first pins 310 adjacent to each other of the first column when viewed from the row direction. The first pins 310 of the third column may be respectively aligned with the first pins 310 of the first column in the row direction.

The first dotting part 30 may be connected to a first driving part. Even though not shown in detail in the drawings, the first driving part may be connected to a controlling part. The first pins 310 of the first dotting part 30 may be moved to a flux storage part storing flux by the first driving part, and then, the flux may be adhered to end portions of the first pins 310.

The second dotting part 32 may include a second body 320 and a plurality of second pins 330 extending from the second body 320 in one direction. The second dotting part 32 may be the substantially same as the first dotting part 30. However, positions of the second pins 330 of the second dotting part 32 may be different from those of the first pins 310 of the first dotting part 30. In more detail, a size and a shape of the second body 320 may be the substantially same as the size and the shape of the first body 300. If the first body 300 is placed on the second body 320, each of the second pins 320 may be disposed between the first pins 310 adjacent to each other. In other words, the first pins 310 and the second pins 320 may be alternately arranged.

The second dotting part 32 may be connected to a second driving part. Even though not shown in detail in the drawings, the second driving part may be connected to a controlling part. The second dotting part 32 may stand ready while the flux is adhered to the first dotting part 30 by the controlling part.

In the present embodiment, the flux dotting apparatus having two dotting parts is described as an example. In another example embodiment, the flux dotting apparatus may include three or more dotting parts. However, the inventive concepts are not limited to the number of dotting parts of the flux dotting apparatus.

The pads of the substrate 100 may be divided into a plurality of pad groups of which each includes a plurality of the pads. The flux may be dotted on the pads of each of the pad groups by each of the dotting parts.

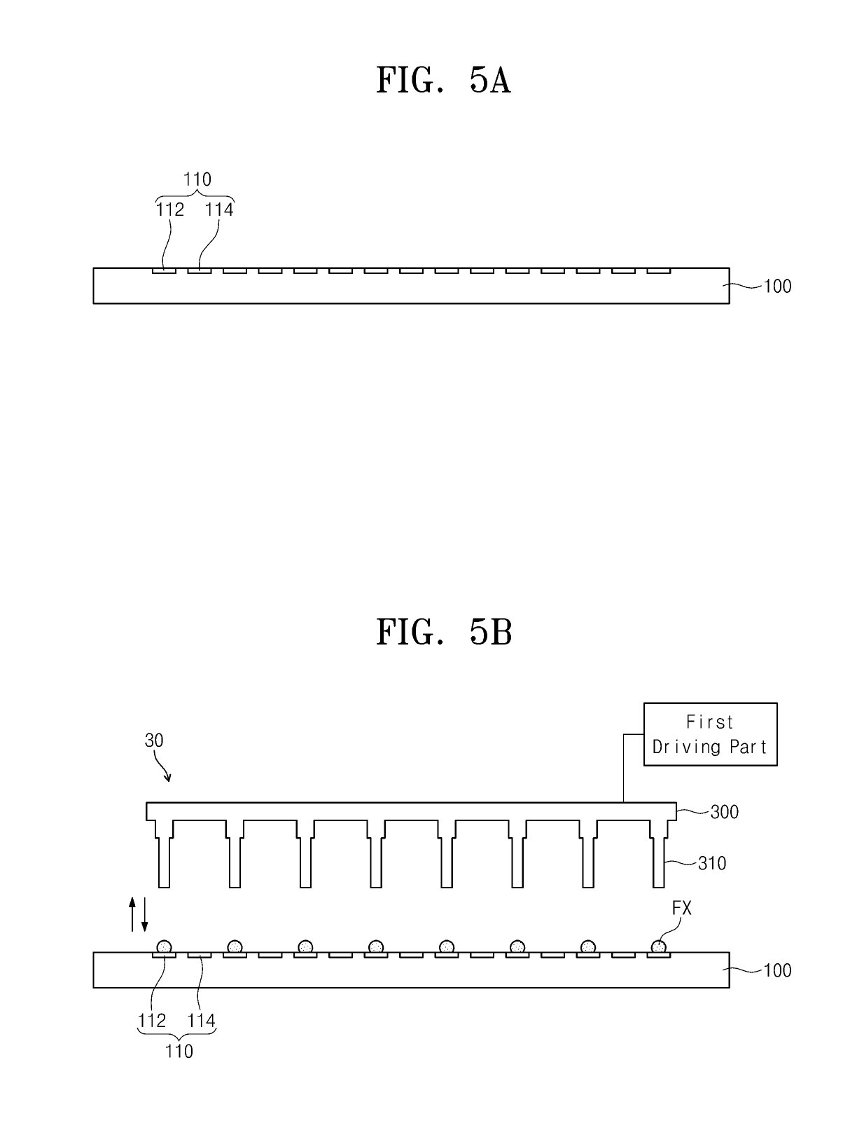

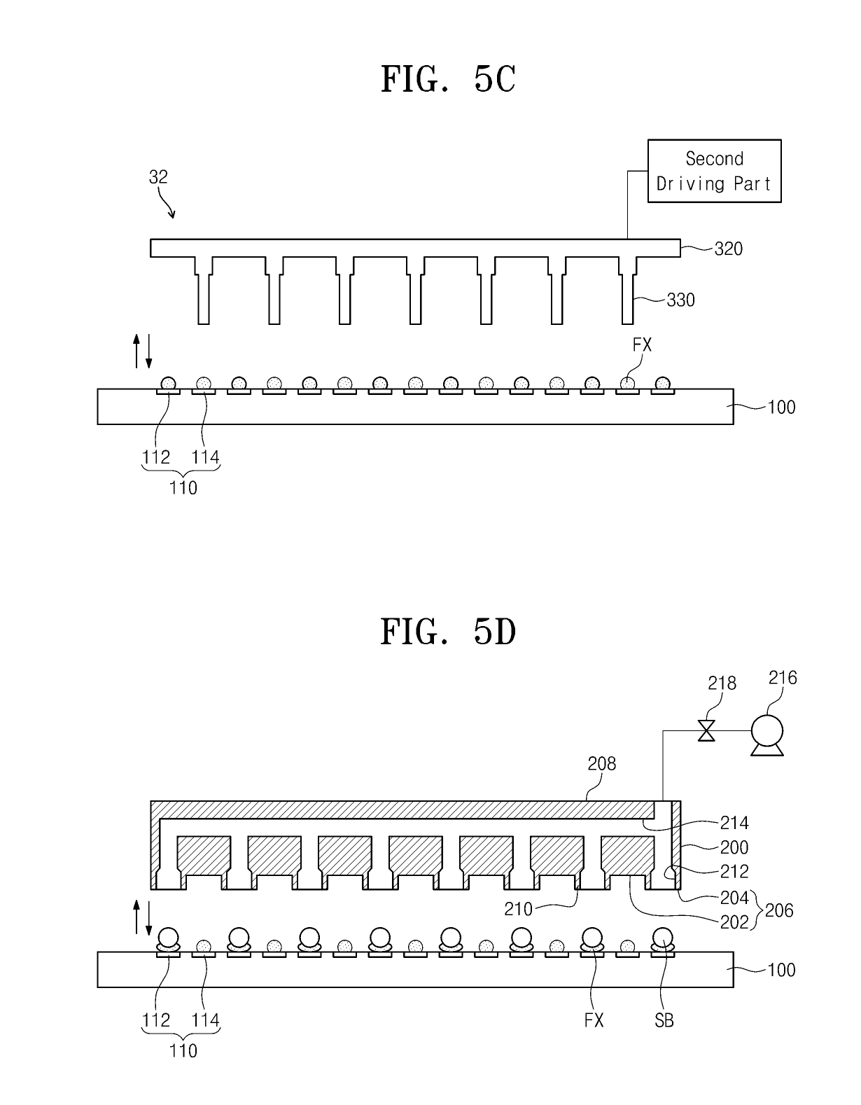

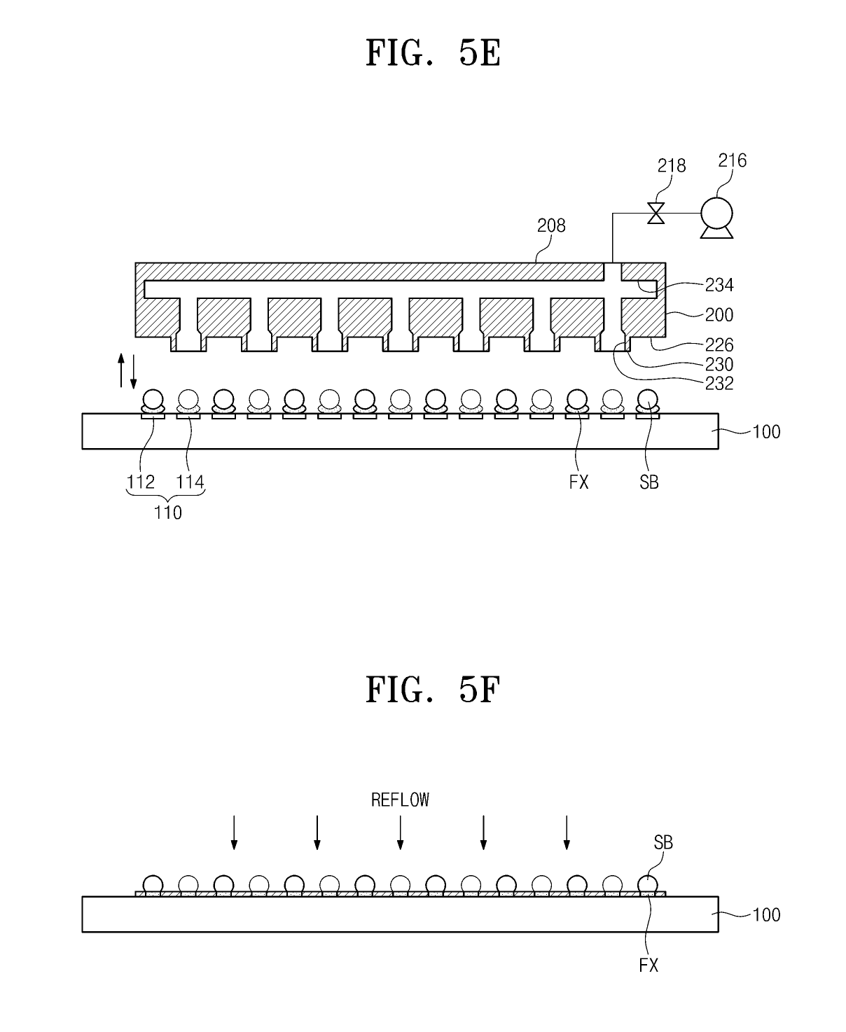

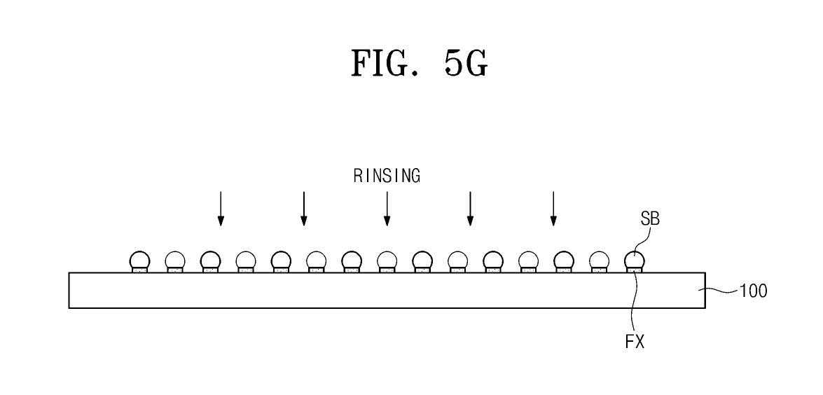

FIGS. 5A through 5G are cross-sectional views illustrating a method of manufacturing a semiconductor package according to an example embodiment of the inventive concepts.

Referring to FIG. 5A, a substrate 100 having pads 110 is prepared. The pads 110 may be formed on one surface of the substrate 100. The substrate 100 may include a printed circuit board, a semiconductor chip, or an interposer.

In an example embodiment, the pads 110 may be arranged along rows and columns by equal distances.

Hereinafter, the pads 110 may include first pads 112 and second pads 114 which are alternately arranged. For example, when a first column, a second column, and a third column are sequentially disposed, the first pads 112 and the second pads 114 of the first column may be alternately arranged in a column direction. The second pads 114 of the second column may be respectively aligned with the first pads 112 of the first column in a row direction, and the first pads 112 of the second column may be respectively aligned with the second pads 114 of the first column in the row direction. The first pads 112 and the second pads 114 of the third column may be aligned with the first pads 112 and the second pads 114 of the first column in the row direction, respectively.

Referring to FIG. 5B, flux FX may be dotted on the first pads 112 using a first dotting part 30 of a flux dotting apparatus. The flux dotting apparatus used in the present embodiment may be the flux dotting apparatus described with reference to FIGS. FIGS. 4A to 4D.

In more detail, the flux FX may be adhered to the first pins 310 of the first dotting part 30 by the first driving part of the flux dotting apparatus. Next, the first pins 310 having the flux FX may be moved onto the first pads 112 by the first driving part to dot the flux FX on the first pads 112.

Referring to FIG. 5C, flux FX may be dotted on the second pads 114 using the second dotting part 32 of the flux dotting apparatus.

In more detail, the flux FX may be adhered to the second pins 330 of the second dotting part 32 by the second driving part of the flux dotting apparatus. Next, the second pins 320 having the flux FX may be moved onto the second pads 114 by the second driving part to dot the flux FX on the second pads 114.

As described above, since the flux dotting apparatus includes two dotting parts 30 and 32, the flux FX may be more easily dotted on the pads 110 even though distances between the pads 110 are relatively small or narrow.

Referring to FIG. 5D, solder balls SB may be attached to the first pads 112 on which the flux FX is dotted.

In an example embodiment, the solder balls SB may be attached to the first pads 112 having the flux FX using the first solder ball attaching apparatus 20 of the solder ball attaching apparatus illustrated in FIGS. 2A and 2B. In more detail, the vacuum pressure may be provided to the first vacuum line 214 and the first vacuum holes 212 connected to the first vacuum line 214 by the first vacuum part 216 of the first solder ball attaching apparatus 20, so the solder balls SB may be held in the first vacuum holes 212. Next, the solder balls SB held in the first vacuum holes 212 may be attached to the first pads 112 using the controlling part of the first solder ball attaching apparatus 20.

Referring to FIG. 5E, solder balls SB may be attached to the second pads 114 on which the flux FX is dotted.

In an example embodiment, the solder balls SB may be attached to the second pads 114 having the flux FX using the second solder ball attaching apparatus 22 illustrated in FIGS. 2C and 2D. In more detail, the vacuum pressure may be provided to the second vacuum line 234 and the second vacuum holes 232 connected to the second vacuum line 234 by the second vacuum part 236 of the second solder ball attaching apparatus 22, so the solder balls SB may be held in the second vacuum holes 232. Next, the solder balls SB held in the second vacuum holes 232 may be attached to the second pads 114 using the controlling part of the second solder ball attaching apparatus 22.

Since the first vacuum holes 212 and the second vacuum holes 232 are disposed to be alternately arranged as described above, the solder balls SB may be more easily attached to the pads 110 of the distances are small or narrow. In addition, since the first and second solder ball attaching apparatuses 20 and 20 use the first vacuum part 216 and the second vacuum part 236 independent of each other, the vacuum pressure may be sufficiently provided to the first and second vacuum holes 212 and 213 while the solder balls SB are attached to the pads 110. On the other hand, the first and second vacuum parts 216 and 236 may be replaced with one vacuum part. In this case, the second line 234 may be closed when the vacuum pressure is provided to the first vacuum holes 212, and thus, a sufficient vacuum pressure may be provided to the first vacuum holes 212.

In the present embodiment, the solder balls SB are attached to using the solder ball attaching apparatus illustrated in FIGS. 2A through 2D. Alternatively, the solder balls SB may be attached to the first and second pads 112 and 114 having the flux FX by the solder ball attaching apparatus illustrated in FIGS. 3A through 3C.

Referring to FIG. 5F, a reflow process may be performed on the substrate 100 having the solder balls SB which are attached to the pads 110 by the flux FX.

The flux FX may react with the solder balls SB during the reflow process, so the solder balls SB may be bonded to the pads 110, respectively. In addition, during the reflow process, the flux FX may be melted to become in contact with the flux FX disposed on neighboring pads 110. However, the flux FX that is not in contact with the solder ball may not react with the solder ball.

Referring to FIG. 5G, the flux which does not react with the solder balls SB during the reflow process between the solder balls SB may be removed from the substrate 100 by a cleaning process (e.g., a rinsing process).

According to some example embodiments of the inventive concepts, the flux may be more easily dotted on the pads near to each other and the solder balls may be more easily bonded to the pads. In addition, the solder ball attaching apparatus includes the first and second vacuum lines respectively connected to the first and second vacuum holes, so the vacuum pressure may be sufficiently provided to the vacuum holes when the solder ball are attached on the pads.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A solder ball attaching apparatus comprising:
first protrusions on a surface of a first body, the first protrusions including first vacuum holes and configured to detachedly hold solder balls, a distance between adjacent ones of the first protrusions being greater than at least a diameter of the solder balls; and
a first vacuum part connected to the first vacuum holes.

2. The solder ball attaching apparatus of claim 1, wherein each of the first protrusions protrudes from the surface of the first body by a height greater than at least the diameter of the solder balls.

3. The solder ball attaching apparatus of claim 1, further comprising:
second protrusions on a surface of a second body, the second protrusions including second vacuum holes and configured to detachedly hold solder balls,
wherein a distance between adjacent ones of the second protrusions is greater than at least the diameter of the solder balls.

4. The solder ball attaching apparatus of claim 3, wherein
the first body is on the second body, and
one of the second protrusions is between adjacent ones of the first protrusions.

5. The solder ball attaching apparatus of claim 3, further comprising:
a first vacuum line connected to the first vacuum holes and the first vacuum part;
a first valve on the first vacuum line;
a second vacuum line connected to the second vacuum holes and the first vacuum part; and
a second valve on the second vacuum line.

6. The solder ball attaching apparatus of claim 3, further comprising:
a second vacuum part connected to the second vacuum holes.

7. The solder ball attaching apparatus of claim 1, wherein the first body includes second vacuum holes extending from the surface of the first body between the adjacent ones of the first protrusions and into the first body.

8. The solder ball attaching apparatus of claim 7, further comprising:
a second vacuum part connected to the second vacuum holes.

9. The solder ball attaching apparatus of claim 8, further comprising:
a first vacuum line connected to the first vacuum holes and the first vacuum part;
a first valve on the first vacuum line;
a second vacuum line connected to the second vacuum holes and the second vacuum part; and
a second valve on the second vacuum line.

10. A flux dotting apparatus comprising:
a first body; and
a plurality of first pins on a surface of the first body, the first pins separated from one another by a distance greater than at least a diameter of a solder ball.

11. The flux dotting apparatus of claim 10, further comprising:
a second body; and
a plurality of second pins on a surface of the second body, the second pins separated from one another by a distance greater than at least the diameter of the solder ball.

12. The flux dotting apparatus of claim 11, wherein
the first body is on the second body, and
one of the second pins is between adjacent ones of the first pins.

13. A solder ball attaching apparatus comprising:
a plurality of first hollow mesas extending in a direction perpendicular to a surface of a first body, the plurality of first hollow mesas defining first vacuum holes configured to detachedly hold solder balls; and
a first vacuum line extending in a direction parallel to the surface of the first body, the first vacuum line connecting the first vacuum holes.

14. The solder ball attaching apparatus of claim 13, wherein each of the plurality of first hollow mesas protrudes from the surface of the first body by a height greater than at least the diameter of the solder balls.

15. The solder ball attaching apparatus of claim 13, further comprising:
a plurality of second hollow mesas on a surface of a second body, the plurality of second hollow mesas including second vacuum holes and configured to detachedly hold solder balls; and
a second vacuum line extending in a direction parallel to the surface of the second body, the second vacuum line connecting the second vacuum holes,
wherein a distance between adjacent ones of the plurality of second hollow mesas is greater than at least the diameter of the solder balls.

16. The solder ball attaching apparatus of claim 15, further comprising:
a first vacuum part connected to the first vacuum holes;
a second vacuum part connected to the second vacuum holes;
a first valve on the first vacuum line connected to the first body; and
a second valve on the second vacuum line connected to the second body,
wherein the first vacuum line is connected to the first vacuum part and the second vacuum line is connected to the second vacuum part.

17. The solder ball attaching apparatus of claim 16, wherein
the first vacuum part is connected to the first body by a surface opposite to the surface including the plurality of first hollow mesas, and
the second vacuum part is connected to the second body by a surface opposite to the surface including the plurality of second hollow mesas.

18. The solder ball attaching apparatus of claim 13, wherein a first set of the first vacuum holes penetrate the plurality of first hollow mesas and a second set of the first vacuum holes extend into the first body between adjacent ones of the plurality of first hollow mesas.

19. The solder ball attaching apparatus of claim 18, further comprising:
a first vacuum part connected to the first set of the first vacuum holes; and
a second vacuum part connected to the second set of the second vacuum holes.

20. The solder ball attaching apparatus of claim 19, further comprising:
a first vacuum line connected to the first set of the first vacuum holes and the first vacuum part;
a first valve on the first vacuum line;
a second vacuum line connected to the second set of the first vacuum holes and the second vacuum part; and
a second valve on the second vacuum line.
